(19) United States
(12) Patent Application Publication
(10) Pub. No.: US 2020/0135898 A1
(43) Pub. Date: Apr. 30, 2020

(54) HARD MASK REPLENISHMENT FOR ETCHING PROCESSES

(71) Applicant: International Business Machines Corporation, Armonk, NY (US)

(72) Inventors: Praveen Joseph, Albany, NY (US); Ekmini Anuja De Silva, Slingerlands, NY (US)

(21) Appl. No.: 16/175,032

(22) Filed: Oct. 30, 2018

(51) Int. Cl. H01L 29/66; H01L 21/8234; H01L 21/033; H01L 21/306; H01L 21/3065; H01L 21/02

(52) U.S. Cl. CPC H01L 29/66795; H01L 21/823431; H01L 21/02233; H01L 21/30604; H01L 21/3065; H01L 21/033

(57) ABSTRACT

Techniques regarding the replenishment of one or more hard mask layers to facilitate one or more etching processes are provided. For example, one or more embodiments described herein can comprise a method, which can comprise replenishing an oxide layer onto a surface of a semiconductor substrate by thermally oxidizing the surface of the semiconductor substrate. The oxide layer can facilitate selective etching of the semiconductor substrate.

### BACKGROUND

The subject disclosure relates to hard mask replenishment for one or more etching processes, and more specifically, to replenishing a hard mask using thermal oxidation techniques to facilitate one or more etching processes.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein methods that can replenish a hard mask for one or more etching processes are described.

According to an embodiment, a method is provided. The method can comprise replenishing an oxide layer onto a surface of a semiconductor substrate by thermally oxidizing the surface of the semiconductor substrate. The oxide layer can facilitate selective etching of the semiconductor substrate.

According to an embodiment, a method is provided. The method can comprise oxidizing a semiconductor substrate to form a hard mask layer on a first surface of the semiconductor substrate. The method can also comprise etching a trench into a second surface of the semiconductor substrate.

According to an embodiment, a method is provided. The method can comprise etching a semiconductor substrate. The etching can form a trench into the semiconductor substrate and can thin a hard mask layer positioned on the semiconductor substrate. The method can also comprise thermally oxidizing the semiconductor substrate to replenish the hard mask layer. Further, the method can comprise etching the semiconductor substrate to deepen the trench within the semiconductor substrate.

### BRIEF DESCRIPTION OF THE DRAWINGS

FIG. 1 illustrates a diagram of an example, non-limiting first stage of a replenishment process that can comprise oxidizing a semiconductor substrate to replenish a hard mask layer for one or more etching processes in accordance with one or more embodiments described herein.

FIG. 2 illustrates a diagram of an example, non-limiting second stage of a replenishment process that can comprise oxidizing a semiconductor substrate to replenish a hard mask layer for one or more etching processes in accordance with one or more embodiments described herein.

FIG. 3 illustrates a diagram of an example, non-limiting third stage of a replenishment process that can comprise oxidizing a semiconductor substrate to replenish a hard mask layer for one or more etching processes in accordance with one or more embodiments described herein.

FIG. 4 illustrates a diagram of an example, non-limiting fourth stage of a replenishment process that can comprise oxidizing a semiconductor substrate to replenish a hard mask layer for one or more etching processes in accordance with one or more embodiments described herein.

FIG. 5 illustrates a diagram of an example, non-limiting fifth stage of a replenishment process that can comprise oxidizing a semiconductor substrate to replenish a hard mask layer for one or more etching processes in accordance with one or more embodiments described herein.

FIG. 6 illustrates a diagram of an example, non-limiting sixth stage of a replenishment process that can comprise oxidizing a semiconductor substrate to replenish a hard mask layer for one or more etching processes in accordance with one or more embodiments described herein.

FIG. 7 illustrates a diagram of an example, non-limiting seventh stage of a replenishment process that can comprise oxidizing a semiconductor substrate to replenish a hard mask layer for one or more etching processes in accordance with one or more embodiments described herein.

FIG. 8 illustrates a diagram of an example, non-limiting eighth stage of a replenishment process that can comprise oxidizing a semiconductor substrate to replenish a hard mask layer for one or more etching processes in accordance with one or more embodiments described herein.

FIG. 9 illustrates a diagram of an example, non-limiting ninth stage of a replenishment process that can comprise oxidizing a semiconductor substrate to replenish a hard mask layer for one or more etching processes in accordance with one or more embodiments described herein.

FIG. 10 illustrates a diagram of an example, non-limiting tenth stage of a replenishment process that can comprise oxidizing a semiconductor substrate to replenish a hard mask layer for one or more etching processes in accordance with one or more embodiments described herein.

FIG. 11 illustrates a flow diagram of an example, non-limiting method that can comprise one or more replenishment processes that can include oxidizing a semiconductor substrate to replenish a hard mask layer for one or more etching processes in accordance with one or more embodiments described herein.

FIG. 12 illustrates a flow diagram of an example, non-limiting method that can comprise one or more replenishment processes that can include oxidizing a semiconductor substrate to replenish a hard mask layer for one or more etching processes in accordance with one or more embodiments described herein.

FIG. 13 illustrates a flow diagram of an example, non-limiting method that can comprise one or more replenishment processes that can include oxidizing a semiconductor substrate to replenish a hard mask layer for one or more etching processes in accordance with one or more embodiments described herein.

FIG. 14 illustrates a flow diagram of an example, non-limiting method that can comprise one or more replenishment processes that can include oxidizing a semiconductor substrate to replenish a hard mask layer for one or more etching processes in accordance with one or more embodiments described herein.

FIG. 15 illustrates a flow diagram of an example, non-limiting method that can comprise one or more replenishment processes that can include oxidizing a semiconductor substrate to replenish a hard mask layer for one or more etching processes in accordance with one or more embodiments described herein.

FIG. 16 illustrates a flow diagram of an example, non-limiting method that can comprise one or more replenishment processes that can include oxidizing a semiconductor substrate to replenish a hard mask layer for one or more etching processes in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details. Additionally, cross-hatching and/or shading can be used throughout the drawings to denote like referenced materials, compositions, and/or features.

In high volume manufacturing of semiconductor devices, high etch rates can be preferred to improve manufacturing throughput. Traditional techniques that can increase etch rates during semiconductor device manufacturing can include, for example: increasing chemical reaction rates of the etching process (e.g., by increasing reaction temperatures), and/or increasing physical sputtering rates by using increased radiofrequency (“RF”) power on an electrode upon which a wafer of the semiconductor device is placed. However, traditional techniques for increasing etch rates can also decrease etch selectivity; thereby, increasing the etching of the one or more hard masks used to facilitate the etching process.

Challenges caused by the increased etching of the hard mask are traditionally met by increasing the thickness of the hard mask. For example, increasing the thickness of the hard mask can compensate for the reduced selectivity of the etch process that can result from the increased etch rates. However, as feature dimensions of the semiconductor devices shrink, increasing the thickness of the hard mask can result in high aspect ratio structures, which can collapse during subsequent manufacturing processes. Additionally, in reactive-ion etching, the increased thickness of the hard mask can also result in increasingly high aspect ratio trenches that ions have to locate to continue the etching process.

Various embodiments described herein can regard methods that facilitate one or more etching processes while minimizing the thickness of the hard masks; thereby reducing one or more aspect ratios exhibited by the semiconductor structure during manufacturing. For example, one or more embodiments described herein can regard the use of one or more thin hard masks that can be replenished after degradation by an etching process. For instance, the one or more hard masks can be replenished by oxidizing (e.g., thermally oxidizing) the semiconductor substrate that is subject to the one or more etching processes. In one or more embodiments, the semiconductor substrate subject to one or more etching processes can comprise silicon and/or can be thermally oxidized to form one or more silicon dioxide layers that can serve to protect one or more portions of the semiconductor substrate from subsequent etch processes (e.g., thereby replenishing the hard mask).

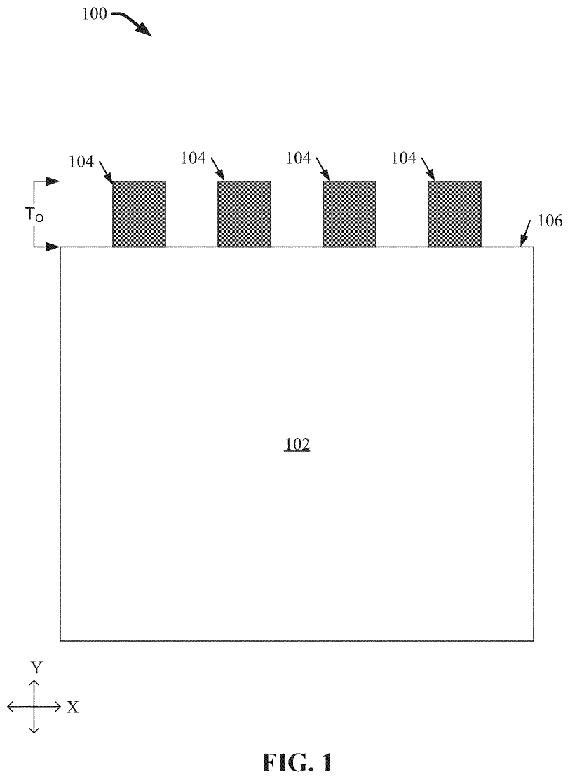

FIG. 1 illustrates a diagram of an example, non-limiting first stage of a replenishment process 100 that can facilitate one or more etching processes in accordance with one or more embodiments described herein. For example, FIG. 1 can depict a semiconductor substrate 102 that can be subject to one or more etching processes to manufacture one or more semiconductor devices (e.g., one or more fin field-effect transistors). Example materials that can comprise the semiconductor substrate 102 can include, but are not limited to: silicon, germanium, silicon carbide, carbon doped silicon, compound semiconductors (e.g., comprising elements from periodic table groups III, IV, and/or V), silicon oxide, a combination thereof, and/or the like. For instance, the semiconductor substrate 102 can be a bulk silicon wafer and/or a silicon-on-insulator (“SOI”) wafer. Additionally, the semiconductor substrate 102 can comprise electronic structures such as isolation wires (not shown). Further, the one or more semiconductor substrate 102 can be characterized by one or more crystalline structures. For example, the semiconductor substrate 102 can comprise silicon <100>, silicon <110>, and/or silicon <111>, as described using Miller indices. One of ordinary skill in the art will readily recognize that the thickness of the semiconductor substrate 102 can vary depending on the composition of the semiconductor substrate 102 and/or the functionality of the semiconductor device being manufactured.

As shown in FIG. 1, one or more hard mask layers 104 can be positioned on a top surface 106 of the semiconductor substrate 102. The one or more hard mask layers 104 can facilitate on more etching processes can be performed on the semiconductor substrate 102. Example etching processes can include, but are not limited to: reactive-ion etching (“RIE”), wet etching, dry etching, plasma etching, sputter etching, a combination thereof, and/or the like. In one or more embodiments, the one or more etching processes can comprise a dry etch using chlorine/hydrogen bromide (“Cl₂/HBr”) chemical reactions. Also, the one or more hard mask layers 104 can be characterized as having greater resistivity to the one or more etching processes than the semiconductor substrate 102. In one or more embodiments, the one or more hard mask layers 104 can be patterned on the top surface 106 such that the one or more etching processes can form one or more structures from the semiconductor substrate 102.

The one or more hard mask layers 104 can comprise, for example, silicon dioxide (“SiO₂”). An original thickness of the one or more hard mask layers 104 (e.g., represented by the “To” arrow shown in FIG. 1) can be greater than or equal to 5 nanometers (nm) and less than or equal to 250 nm. One of ordinary skill in the art can recognize that the original thickness of the one or more hard mask layers 104 can depend on: the composition of the one or more hard mask layers 104, the critical dimension of the fin and/or column being etched, and/or the type of etching process utilized.

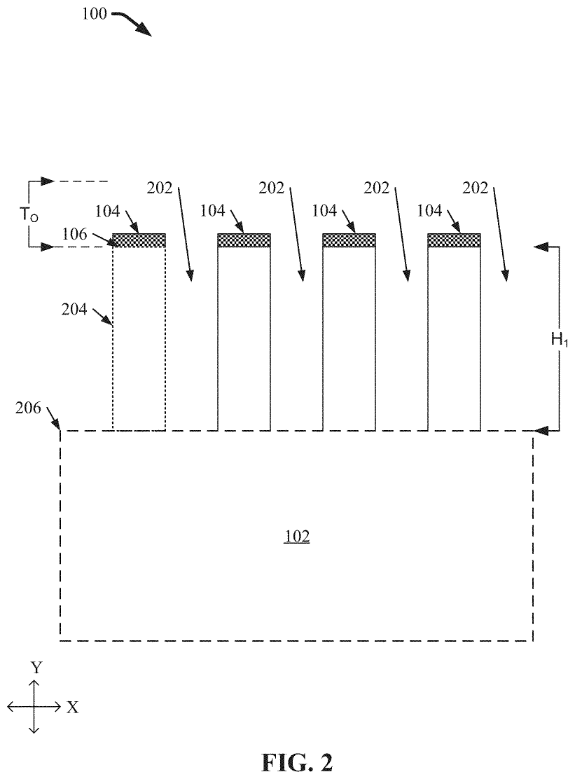

FIG. 2 illustrates a diagram of an example, non-limiting second stage of a replenishment process 100 that can facilitate one or more etching processes in accordance with one or more embodiments described herein. Repetitive description of like elements employed in other embodiments described herein is omitted for sake of brevity. As shown in FIG. 2, the one or more etching processes remove one or more portions of the semiconductor substrate 102 to form one or more trenches 202. The one or more trenches 202 can define one or more columns 204 of the semiconductor substrate 102 extending from a base 206 of the semiconductor substrate 102. For example, FIG. 2 depicts four columns 204 formed by the one or more etching processes, wherein a first column is delineated with dashed lines for clarity. Additionally, the base 206 is delineated with dashed lines in FIG. 2. Further, as shown in FIG. 2, the top surface 106 can be maintained at the distal ends of the one or more columns 204. For example, the one or more columns 204 and/or the base 206 can form a fin structure of the semiconductor substrate 102 (e.g., a fin structure that can facilitate manufacturing of one or more fin field-effect transistors).

The one or more etching processes can form the one or more trenches 202 at exposed portions of the top surface 106. In other words, the one or more etching processes can remove portions of the top surface 106 not protected by the one or more hard mask layers 104 to form the one or more trenches 202. In contrast, portions of the top surface 106 covered by the one or more hard mask layers 104 can be protected from the one or more etching processes.

Also shown in FIG. 2, the one or more etching processes can degrade the one or more hard mask layers 104. For example, the one or more etching processes can thin the one or more hard mask layers 104 (e.g., along the “Y” axis shown in FIG. 2). For example, FIG. 2 can illustrate the thinning of the one or more hard mask layers 104 by presenting the original thickness (e.g., represented by the “To” arrow shown in FIG. 2) of the one or more hard mask layers 104 prior to the one or more etching processes.

The thinning of the one or more hard mask layers 104 can limit the depth to which the one or more trenches 202 can be formed into the semiconductor substrate 102; thereby limiting a first height (e.g., represented by the “H₁” arrow shown in FIG. 2) of the one or more columns 204. For example, wherein the semiconductor substrate 102 comprises silicon and the one or more hard mask layers 104 comprise silicon dioxide, the one or more hard mask layers 104 can exhibit a selectivity of ten during a dry etch process using Cl₂/HBr chemical reactions; thus, the depth of the one or more trenches 202 (e.g., and thereby the first height of the one or more columns 204) can be limited to less than or equal to ten times the initial thickness of the one or more hard mask layers 104. However, one or more embodiments of the replenishment processes 100 can comprise extending the one or more trenches 202 with one or more subsequent etching processes that can be facilitated by replenishment of the thickness of the one or more hard mask layers 104.

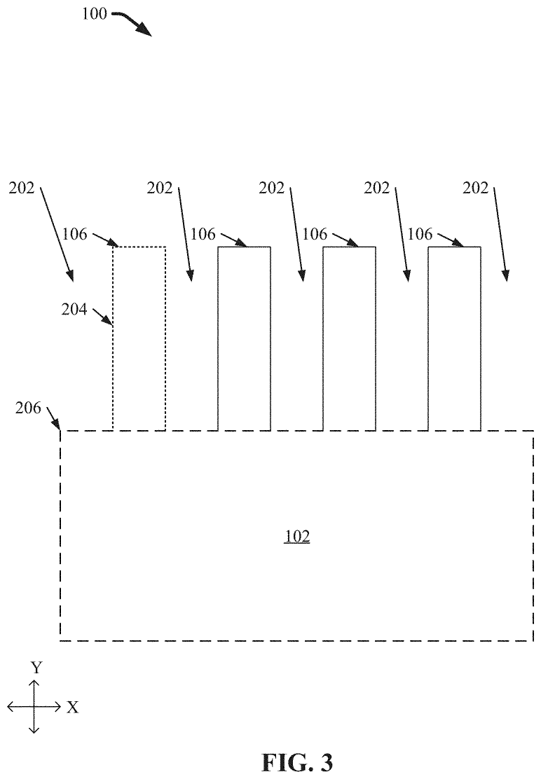

FIG. 3 illustrates a diagram of an example, non-limiting third stage of a replenishment process 100 that can facilitate one or more etching processes in accordance with one or more embodiments described herein. Repetitive description of like elements employed in other embodiments described herein is omitted for sake of brevity. As shown in FIG. 3, the one or more hard mask layers 104 (e.g., thinned from the one or more etching processes) can be removed from the one or more columns 204 to facilitate replenishment of the one or more hard mask layers 104. For example, the one or more hard mask layers 104 can be removed to expose the top surface 106 located at the distal ends of the one or more columns 204. Example processes that can facilitate the removal of the one or more thinned hard mask layers 104 can include, but are not limited to: wet chemical etch processes, and/or the like.

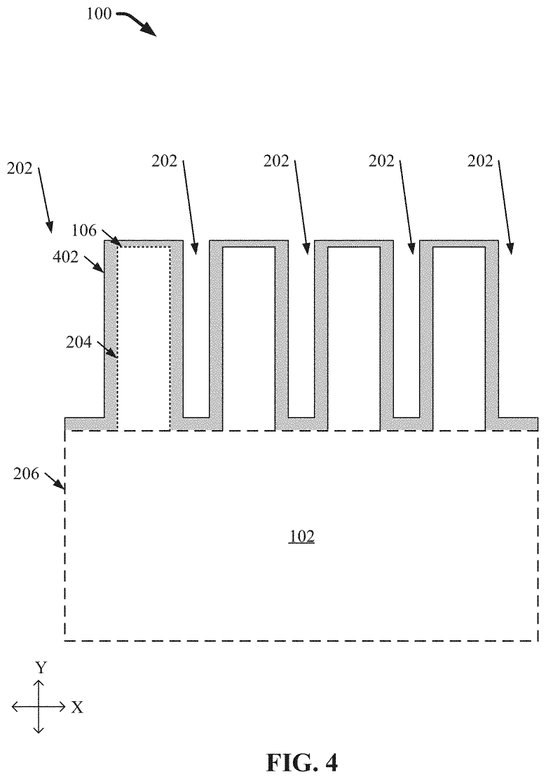

FIG. 4 illustrates a diagram of an example, non-limiting fourth stage of a replenishment process 100 that can facilitate one or more etching processes in accordance with one or more embodiments described herein. Repetitive description of like elements employed in other embodiments described herein is omitted for sake of brevity.

As shown in FIG. 4, during the fourth stage one or more protective layers 402 can be deposited onto the top surface 106 and/or into the one or more trenches 202. For example, the one or more protective layers 402 can be deposited onto the top of the one or more columns 204, onto the sides (e.g., the left side and/or the right side) of the one or more columns 204, and/or onto the base 206 of the semiconductor substrate 102. In other words, the one or more columns 204 can be encapsulated by the one or more protective layers 402 and/or the base 206 of the semiconductor substrate 102. The one or more protective layers 402 can comprise a material resistant to thermal oxidation. In various embodiment, the one or more protective layers 402 can comprise silicon nitride.

Additionally, in one or more embodiments the one or more protective layers 402 can be deposited more thickly within the one or more trenches 202 than on the top surface 106 located at the distal ends of the one or more columns 204. As shown in FIG. 4, the one or more protective layers 402 can have a first thickness at positions located within the one or more trenches 202 (e.g., on the base 206 of the semiconductor substrate 102 and/or on the sides of the one or more columns 204) and/or a second thickness at positions located on the top surface 106 at the distal ends of the columns 204; wherein the first thickness can be greater than the second thickness. For example, the first thickness can be two to five times thicker than the second thickness. In one or more embodiments, the one or more protective layers 402 can be deposited via a selective atomic layer deposition (“ALD”) process with post-dose treatment, which can facilitate the varying thicknesses of the one or more protective layers 402 described herein (e.g., wherein the one or more protective layers 402 are thinnest at positions on the top surface 106 located at the distal ends of the columns 204).

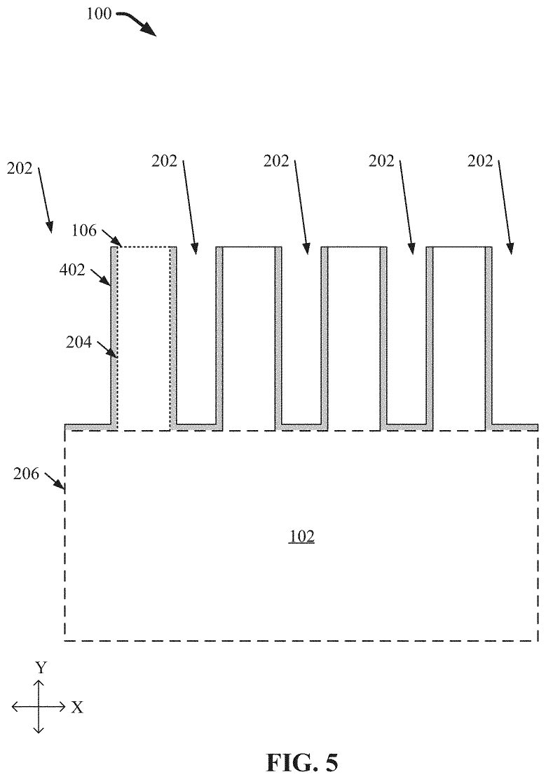

FIG. 5 illustrates a diagram of an example, non-limiting fifth stage of a replenishment process 100 that can facilitate one or more etching processes in accordance with one or more embodiments described herein. Repetitive description of like elements employed in other embodiments described herein is omitted for sake of brevity. As shown, in FIG. 5, the one or more protective layers 402 can be thinned during the fifth stage of the replenishment process 100. For example, the one or more protective layers 402 can be subject to one or more etching processes, including, but not limited to: RIE, wet etching, dry etching, plasma etching, sputter etching, a combination thereof, and/or the like.

As shown in FIG. 5, the etching can remove the thinnest portions of the one or more protective layers 402 while thinning the thickest portions of the one or more protective layers 402. For example, one or more etching processes can remove the one or more protective layers 402 from positions at the top surface 106 at the distal ends of the columns 204; thereby exposing the top surface 106 to the environment. Additionally, the one or more etching processes can thin the one or more protective layers 402 from positions within the one or more trenches 202 (e.g., on the base 206 of the semiconductor substrate 102 and/or on the sides of the one or more columns 204). In other words, the one or more etching processes during the fifth stage can expose the top surface 106 (e.g., located at the distal ends of the one or more columns 204) to the environment surrounding the semiconductor substrate 102 while leaving the surfaces that define the one or more trenches 202 protected from the environment by the one or more protective layers 402.

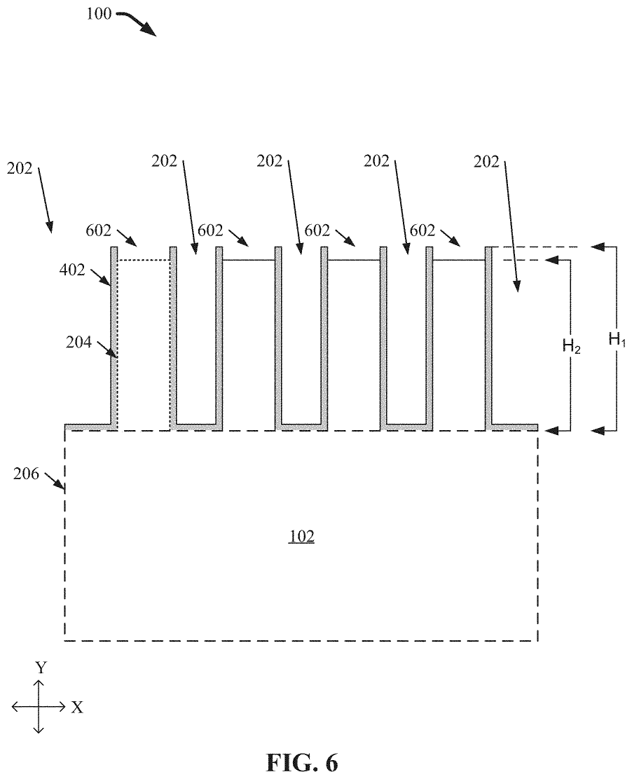

FIG. 6 illustrates a diagram of an example, non-limiting sixth stage of a replenishment process 100 that can facilitate one or more etching processes in accordance with one or more embodiments described herein. Repetitive description of like elements employed in other embodiments described herein is omitted for sake of brevity. As shown in FIG. 6, one or more recesses 602 can be formed into the top surfaces 106 at the distal ends of the one or more columns 204.

During the sixth stage, one or more etching processes can remove semiconductor material from the top surfaces 106 to shorten the one or more columns 204 from the first height (e.g., represented by the “H₁” arrow in FIG. 6) to a second height (e.g., represented by the “H₂” arrow in FIG. 6). Further, the second height (e.g., represented by the “H₂” arrow in FIG. 6) can be shorter (e.g., along the “Y” axis shown in FIG. 6) than the height of the one or more protective layers 402 (e.g., wherein the height of the one or more protective layers 402 can be substantially equal to the first height (“H₁”) of the columns 204). As a result of the etching during the sixth stage, the one or more protective layers 402 can extend from the base 206 of the semiconductor substrate 102 to a height (e.g., along the “Y” axis shown in FIG. 6) greater than the second height (e.g., represented by the “H₂” arrow in FIG. 6) of the one or more columns 204. Example etching processes that can facilitate the reduction of the one or more columns' 204 height can include, but not limited to: RIE, wet etching, dry etching, plasma etching, sputter etching, a combination thereof, and/or the like.

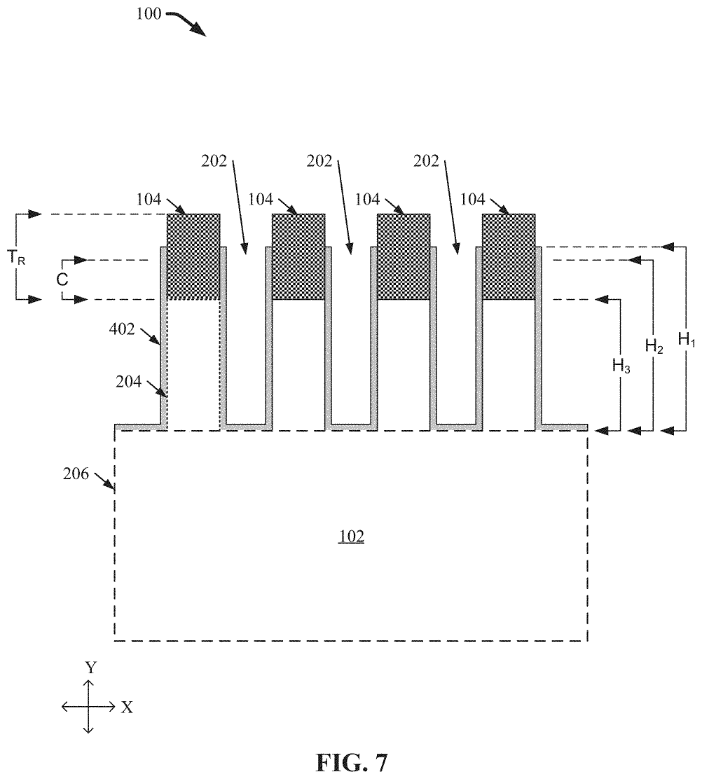

FIG. 7 illustrates a diagram of an example, non-limiting seventh stage of a replenishment process 100 that can facilitate one or more etching processes in accordance with one or more embodiments described herein. Repetitive description of like elements employed in other embodiments described herein is omitted for sake of brevity.

During the seventh stage, the one or more hard mask layers 104 can be replenished by the replenishment process 100. For example, the semiconductor substrate 102 can be thermally oxidized to induce growth of an oxide at the distal ends of the one or more columns 204. For instance, wherein the semiconductor substrate 102 comprises silicon, thermal oxidation of the semiconductor substrate 102 can form one or more hard mask layers 104 comprising silicon dioxide. In one or more embodiments, thermal oxidation can comprise, for example: dry oxidation process, wet oxidation processes, mixed flow processes (e.g., wherein oxygen is mixed with an agent such as water, hydrochloric acid, and/or chlorine), a combination thereof, and/or the like. Further, the thermal oxidation can be performed at elevated temperatures (e.g., greater than or equal to 700 degrees Celsius (° C.) and less than or equal to 1500° C.).

As shown, in FIG. 7, the hard mask layers 104 can be replenished at the distal ends of the one or more columns 204 (e.g., on the exposed and/or recessed portions of the top surface 106). The one or more protective layers 402 can delineate the locations where the one or more hard mask layers 104 can be replenished and/or the direction of oxide growth that results from the thermal oxidation. For example, portions of the semiconductor substrate 102 protected by the one or more protective layers 402 (e.g., surfaces of the semiconductor substrate 102 that define the one or more trenches 202 and/or the base 206) can remain free from oxidation. In contrast, portions of the semiconductor substrate 102 not protected by the one or more protective layers 402 (e.g., the recessed top surface 106 of the semiconductor substrate 102 located at the distal ends of the one or more columns 204) can be subject to oxidation by one or more thermal oxidation processes performed during the seventh stage of replenishment. Also, as shown in FIG. 7, the one or more protective layers 402 can guide the growth of the one or more hard mask layers 104 (e.g., comprising the resulting one or more oxides) along the length of the one or more columns 204 (e.g., along the “Y” axis shown in FIG. 7).

The thermal oxidation can replenish the one or more hard mask layers 104 to a replenished thickness (e.g., represented by the “T_{R}” arrow shown in FIG. 7) that is a function of the amount of semiconductor substrate 102 consumed by the chemical reactions of the thermal oxidization (e.g., represented by the “C” arrow shown in FIG. 7). For instance, wherein the seventh stage comprises thermally oxidizing silicon (e.g., which can comprise the semiconductor substrate 102), one unit of silicon dioxide (e.g., which can comprise the one or more hard mask layers 104) can be formed from every 0.46 units of silicon oxidized. As shown in FIG. 7, oxidizing a portion of the one or more columns 204 can form one or more hard mask layers 104 that can have a replenished thickness (e.g., represented by the “T_{R}” arrow shown in FIG. 7) that is greater than the thickness of the oxidized portions of the one or more columns 204 (e.g., represented by the “C” arrow shown in FIG. 7). Thus, the replenished thickness (e.g., represented by the “T_{R}” arrow shown in FIG. 7) of the one or more hard mask layers 104 can depend on one or more parameters of the thermal oxidation. One of ordinary skill in the art will recognize that the amount of semiconductor substrate 102 subject to oxidation can be controlled via the manipulation of one or more thermal oxidation parameters, such as, but not limited to: the oxidant species used in the thermal oxidation process, the temperature and/or pressure of the environment surrounding the semiconductor substrate 102 during the thermal oxidation process, the crystal orientation of the semiconductor substrate 102, the oxidation time duration, a combination thereof, and/or the like. For example, the replenished thickness (e.g., represented by the “T_{R}” arrow shown in FIG. 7) can be greater than or equal to 5 nm and less than or equal to 500 nm.

In one or more embodiments, the replenished thickness (e.g., represented by the “T_{R}” shown in FIG. 7) of the one or more hard mask layers 104 can be equal to the original thickness (e.g., represented by the “To” shown in FIG. 1) of the one or more hard mask layers 104. In one or more embodiments, the replenished thickness (e.g., represented by the “T_{R}” shown in FIG. 7) of the one or more hard mask layers 104 can be less than the original thickness (e.g., represented by the “To” shown in FIG. 1) of the one or more hard mask layers 104. In one or more embodiments, the replenished thickness (e.g., represented by the “T_{R}” shown in FIG. 7) of the one or more hard mask layers 104 can be greater than the original thickness (e.g., represented by the “To” shown in FIG. 1) of the one or more hard mask layers 104. Further, as shown in FIG. 7, at least because a portion of the one or more hard mask layers 104 is replenished from oxidation of the columns 204 of the semiconductor substrate 102 itself, the thermal oxidation can shorten the height (e.g., along the “Y” axis shown in FIG. 7) of the one or more columns 204 to a third height (e.g., represented by the “H₃” arrow shown in FIG. 7).

In one or more embodiments, the one or more hard mask layers 104 can have the same, or substantially the same, composition at the first stage of the replenishment process 100 and the seventh stage of the replenishment processes 100. Alternatively, in one or more embodiments the one or more hard mask layers 104 can have a different composition at the first stage of the replenishment process 100 than the seventh stage of the replenishment processes 100.

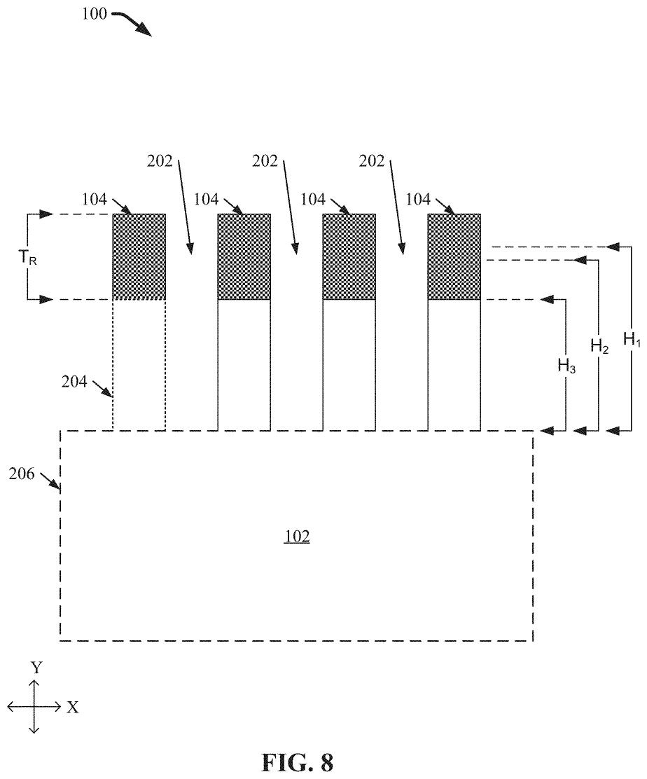

FIG. 8 illustrates a diagram of an example, non-limiting eighth stage of a replenishment process 100 that can facilitate one or more etching processes in accordance with one or more embodiments described herein. Repetitive description of like elements employed in other embodiments described herein is omitted for sake of brevity. As shown in FIG. 8, at the eighth stage, the one or more protective layers 402 can be removed from the semiconductor substrate 102.

For example, the one or more protective layers 402 can be etched away from the one or more trenches 202. Thus, the base 206 of the semiconductor substrate 102 can be exposed to the environment to facilitate one or more further manufacturing processes (e.g., one or more further etching processes). Additionally, removal of the one or more protective layers 402 can render the surfaces of the semiconductor substrate 102 that define the one or more trenches 202 exposed to the environment surrounding the semiconductor substrate 102; thereby facilitating one or more further developments to the one or more trenches 202 (e.g., a deepening of the one or more trenches 202 into the base 206 of the semiconductor substrate 102). Example etch processes that can facilitate the removal of the one or more protective layers 402 can include, but are not limited to: RIE, wet etching, dry etching, plasma etching, sputter etching, a combination thereof, and/or the like.

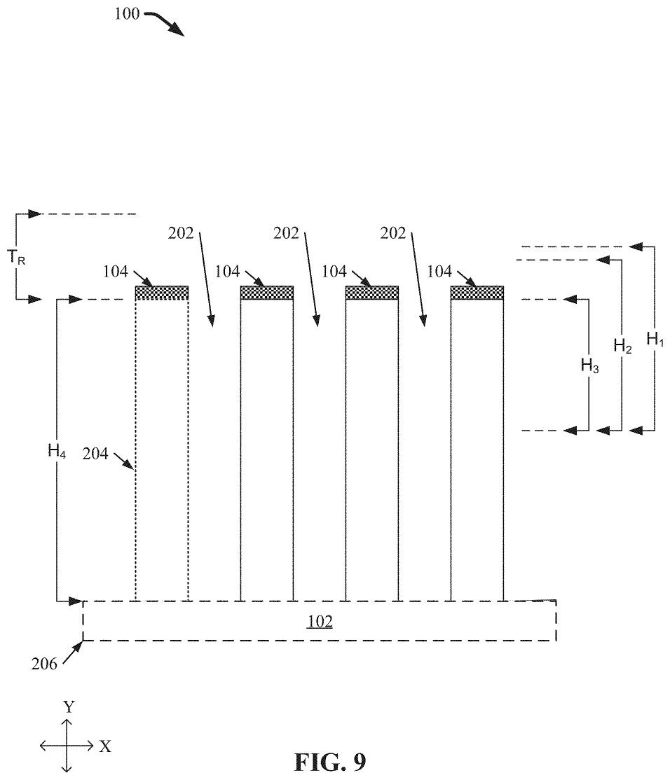

FIG. 9 illustrates a diagram of an example, non-limiting ninth stage of a replenishment process 100 that can facilitate one or more etching processes in accordance with one or more embodiments described herein. Repetitive description of like elements employed in other embodiments described herein is omitted for sake of brevity. As shown in FIG. 9, the semiconductor substrate 102 can be further etched to deepen the one or more one or more trenches 202.

For example, the replenished one or more hard mask layers 104 can protect the top surface 106 located at the distal ends of the one or more columns 204 from being subject to the one or more etching processes, while leaving the remaining surfaces of the semiconductor substrate 102 exposed to the one or more etching processes. For instance, the one or more etching processes can remove semiconductor material from the bottom of the one or more trenches 202; thereby diminishing the thickness (e.g., along the “Y” axis shown in FIG. 9) of the base 206 and/or increasing the height (e.g., along the “Y” axis shown in FIG. 9) of the one or more columns 204. In one or more embodiments, the etching at the ninth stage can increase the height of the one or more columns 204 to a fourth height (e.g., delineated by the “H₄” arrow shown in FIG. 9). Further, the fourth height (e.g., delineated by the “H₄” arrow shown in FIG. 9) can be greater than the previous heights exhibited by the one or more columns 204 (e.g., the first height represented by the “H₁” arrow, the second height represented by the “H₂” arrow, and/or the third height represented by the “H₃” arrow).

Further, the one or more etching processes that deepen the one or more trenches 202 (e.g., thereby increasing the height of the one or more columns 204) can also diminish the thickness of the one or more hard mask layers 104. For example, the diminishment of the one or more hard mask layers 104 is depicted in FIG. 9 through the illustration of the replenished thickness (e.g., represented by the “T_{R}” arrow shown in FIG. 9) previously exhibited by the one or more hard mask layers 104.

The thinning of the one or more hard mask layers 104 can limit the depth to which the one or more trenches 202 can be formed into the semiconductor substrate 102; thereby limiting the fourth height (e.g., represented by the “H₄” arrow shown in FIG. 9) of the one or more columns 204. For example, wherein the semiconductor substrate 102 comprises silicon and the one or more hard mask layers 104 comprise silicon dioxide, the one or more hard mask layers 104 can exhibit a selectivity of ten during a dry etch process using Cl₂/HBr chemical reactions; thus, the depth of the one or more trenches 202 (e.g., and thereby the first height of the one or more columns 204) can be limited to less than or equal to ten times the initial thickness of the one or more hard mask layers 104.

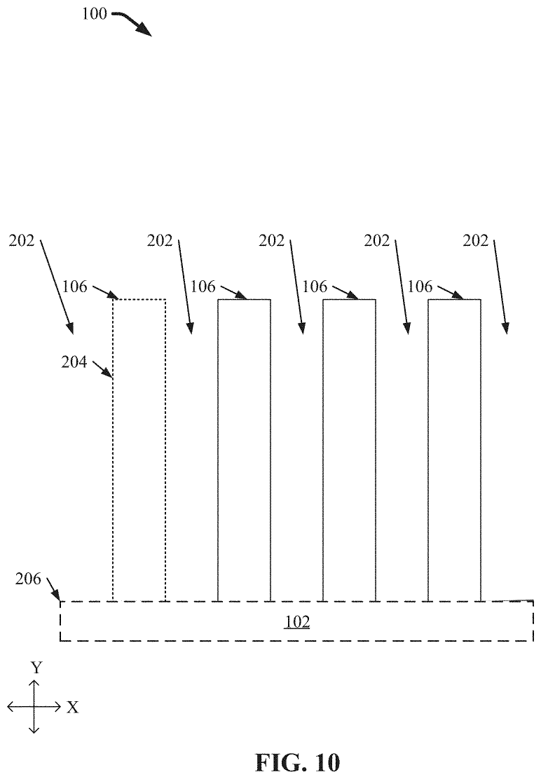

FIG. 10 illustrates a diagram of an example, non-limiting tenth stage of a replenishment process 100 that can facilitate one or more etching processes in accordance with one or more embodiments described herein. Repetitive description of like elements employed in other embodiments described herein is omitted for sake of brevity. As shown in FIG. 10, at the tenth stage the one or more hard mask layers 104 can be removed from the semiconductor substrate 102 (e.g., from the one or more top surfaces 106 located at the distal ends of the one or more columns 204).

Removal of the one or more hard mask layers 100 can facilitate further manufacturing processes of the subject semiconductor device. For example, the third stage through the ninth stage of the replenishment process 100 described herein can be repeated to further heighten the one or more columns 204. Advantageously, by replenishing the thickness of the one or more hard mask layers 104, the replenishment process 100 can facilitate formation of one or more columns 204 having large heights (e.g., the fourth height represented by the “H₄” arrow shown in FIG. 9) while using thin hard mask layers 104 (e.g., the original thickness represented by the “To” arrow shown in FIG. 1 and/or the replenished thickness represented by the “T_{R}” arrow shown in FIG. 8). Additionally, since the replenishment process 100 replenishes the one or more hard mask layers 104 through oxidation of the semiconductor substrate 102 itself, additional materials need not be deposited onto the semiconductor substrate 102; thereby minimizing complexity and/or cost of the manufacturing process being facilitated by the replenishment process 100.

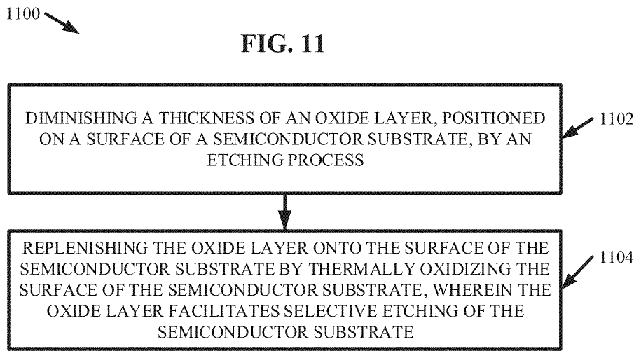

FIG. 11 illustrates a flow diagram of an example, non-limiting method 1100 that can facilitate replenishment of one or more hard mask layers 104 to facilitate one or more etching processes in accordance with one or more embodiments described herein. Repetitive description of like elements employed in other embodiments described herein is omitted for sake of brevity.

At 1102, the method 1100 can comprise diminishing a thickness of an oxide layer, positioned on a surface of a semiconductor substrate 102, by one or more etching processes. For example, the diminishing at 1102 can be performed in accordance with the second stage of the replenishment process 100 described herein. For instance, the oxide layer can be one or more hard mask layers 104 utilized to facilitate one or more etching processes. Further, the one or more hard mask layers 104 can be positioned on the top surface 106 of the semiconductor substrate 102. Additionally, the one or more etching processes can diminish the one or more hard mask layers 104 from an original thickness (e.g., represented by “To” in FIG. 2). In one or more embodiments, the diminishing at 1102 can occur as result of forming one or more trenches 202 to define one or more fin structures (e.g., comprising one or more columns 204 extending from a common base 206) of the semiconductor substrate 102. Example etching processes can include, but are not limited to: RIE, wet etching, dry etching, plasma etching, sputter etching, a combination thereof, and/or the like.

At 1104, the method 1100 can comprise replenishing the oxide layer (e.g., the one or more hard mask layers 104) onto the surface (e.g., the top surface 106) of the semiconductor substrate 102 by thermally oxidizing the surface of the semiconductor substrate 102, wherein the oxide layer can facilitate selective etching of the semiconductor substrate 102. For example, the replenishing at 1104 can be performed in accordance with the third, fourth, fifth, sixth, seventh, and/or eighth stages of the replenishment process 100 described herein. For instance, in one or more embodiments the replenishing at 1104 can comprise forming one or more protective layers 402 to protect the semiconductor substrate 102 from oxidation, while exposing the top surface 106 of the semiconductor substrate 102 to facilitate oxidation (e.g., and thereby formation of the oxide layer). For example, the one or more protective layers 402 can define the locations of oxidation and/or direct the growth of oxide. By replenishing the thickness of the oxide layer (e.g., the one or more hard mask layers 104), the method 1100 can facilitate one or more deep etching processes while using thin masking layers.

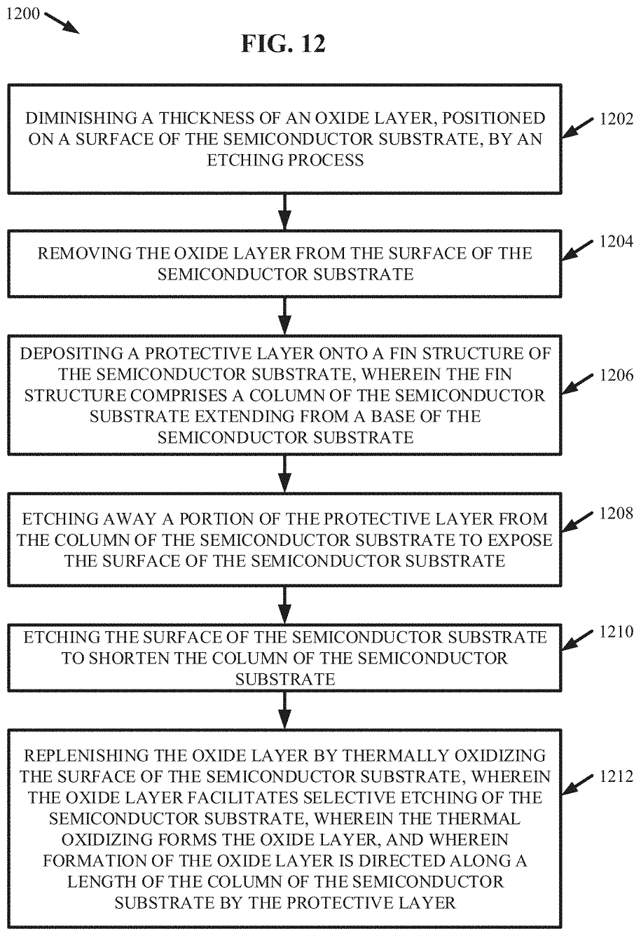

FIG. 12 illustrates a flow diagram of an example, non-limiting method 1200 that can facilitate replenishment of one or more hard mask layers 104 to facilitate one or more etching processes in accordance with one or more embodiments described herein. Repetitive description of like elements employed in other embodiments described herein is omitted for sake of brevity.

At 1202, the method 1200 can comprise diminishing a thickness of one or more oxide layers, positioned on a surface of a semiconductor substrate 102, by one or more etching processes. For example, the diminishing at 1202 can be performed in accordance with the second stage of the replenishment process 100 described herein. For instance, the oxide layer can be one or more hard mask layers 104 utilized to facilitate one or more etching processes. Further, the one or more hard mask layers 104 can be positioned on the top surface 106 of the semiconductor substrate 102. Additionally, the one or more etching processes can diminish the one or more hard mask layers 104 from an original thickness (e.g., represented by “To” in FIG. 2). In one or more embodiments, the diminishing at 1202 can occur as result of forming one or more trenches 202 to define one or more fin structures (e.g., comprising one or more columns 204 extending from a common base 206) of the semiconductor substrate 102. Example etching processes can include, but are not limited to: RIE, wet etching, dry etching, plasma etching, sputter etching, a combination thereof, and/or the like.

At 1204, the method 1200 can comprise removing the one or more oxide layers (e.g., one or more hard mask layers 104) from the surface (e.g., the top surface 106) of the semiconductor substrate 102. For example, removing the oxide layer at 1204 can be performed in accordance with the third stage of the replenishment process 100 described herein. For instance, the one or more oxide layers can be removed by one or more etch processes, which can include, but are not limited to: RIE, wet etching, dry etching, plasma etching, sputter etching, a combination thereof, and/or the like.

At 1206, the method 1200 can comprise depositing one or more protective layers 402 onto a fin structure of the semiconductor substrate 102, wherein the fin structure can comprise one or more columns 204 of the semiconductor substrate 102 extending from a base 206 of the semiconductor substrate 102. For example, the depositing at 1206 can be performed in accordance with the fourth stage of the replenishment process 100 described herein. For instance, the one or more protective layers 402 can be deposited more thickly in the one or more trenches 202 adjacent to the one or more columns 204 than on a top surface 106 of the semiconductor substrate 102, which can be located at the distal ends of the one or more columns 204. An example deposition method that can facilitate the varying thickness of the one or more protective layers 402 can be an ALD with post-dose treatment. Additionally, one of ordinary skill in the art will recognize that alternate deposition methods can also be employed to facilitate the depositing at 1206.

At 1208, the method 1200 can comprise etching away a portion of the one or more protective layers 402 from the one or more columns 204 of semiconductor substrate 102 to expose the surface (e.g., the top surface 106) of the semiconductor substrate 102. For example, the etching at 1208 can be performed in accordance with the fifth stage of the replenishment process 100 described herein. For instance, the etching at 1208 can thin entirety of the one or more protective layers 402; thereby removing the thinnest portions of the one or more protective layers 402 from the semiconductor substrate 102 (e.g., located on the top surface 106), while leaving the thicker portions of the one or more semiconductor substrate 102 (e.g., located within the one or more trenches 202).

At 1210, the method 1200 can comprise etching the surface (e.g., the top surface 106) of the semiconductor substrate 102 to shorten the one or more columns 204 of the semiconductor substrate 102. For example, the etching at 1210 can be performed in accordance with the sixth stage of the replenishment process 100 described herein. For instance, the etching at 1208 can form one or more recesses 602 into the top surface 106 of the semiconductor substrate 102 such that the one or more protective layers 402 can extend beyond the length of the one or more columns 204.

At 1212, the method 1200 can comprise replenishing the one or more oxide layers (e.g., one or more hard mask layers 104) by thermally oxidizing the surface (e.g., the top surface 106) of the semiconductor substrate 102, wherein the one or more oxide layers can facilitate selective etching of the semiconductor substrate 102. The thermal oxidization can form the one or more oxide layers. Also, the formation of the one or more oxide layers can be directed along a length (e.g., along the “Y” axis shown in FIG. 7) of the one or more columns 204 of the semiconductor substrate 102 by the one or more protective layers 402. For example, the replenishing at 1212 can be performed in accordance with the seventh stage of the replenishment process 100 described herein.

Optionally, the method 1200 can further comprise removing the one or more protective layers 402 from the semiconductor substrate 102 (e.g., in accordance with the eighth stage of the replenishment process 100 described herein) and/or subsequently etching the semiconductor substrate 102 to further define the one or more trenches 202 and thereby the one or more columns 204 (e.g., in accordance with the ninth stage of the replenishment process 100 described herein).

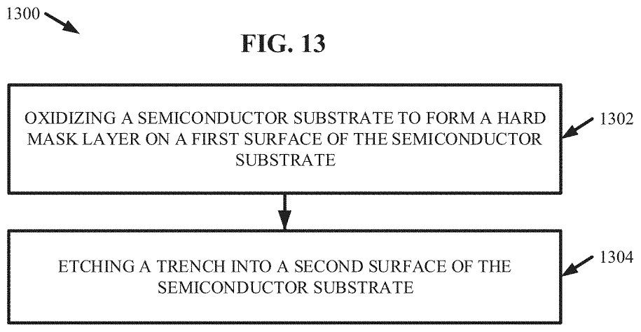

FIG. 13 illustrates a flow diagram of an example, non-limiting method 1300 that can facilitate replenishment of one or more hard mask layers 104 to facilitate one or more etching processes in accordance with one or more embodiments described herein. Repetitive description of like elements employed in other embodiments described herein is omitted for sake of brevity.

At 1302, the method 1300 can comprise oxidizing a semiconductor substrate 102 to form one or more hard mask layers 104 on a first surface (e.g., a top surface 106) of the semiconductor substrate 102. For example, the oxidizing at 1302 can be performed in accordance with the seventh stage of the replenishment process 100 described herein. For instance, the oxidizing at 1302 can be directed by one or more protective layers 402 to selectively position the replenishment of the one or more hard mask layers 104 onto the semiconductor substrate 102.

At 1304, the method 1300 can comprise etching one or more trenches 202 into a second surface of the semiconductor substrate 102 (e.g., into a base 206 of the semiconductor substrate 102). For example, the etching at 1304 can be performed in accordance with the ninth stage of the replenishment process 100 described herein. Thus, the semiconductor substrate 102 subject to etching can itself provide the materials to form the one or more hard mask layers 104, thereby alleviating a necessity to deposit additional hard mask materials.

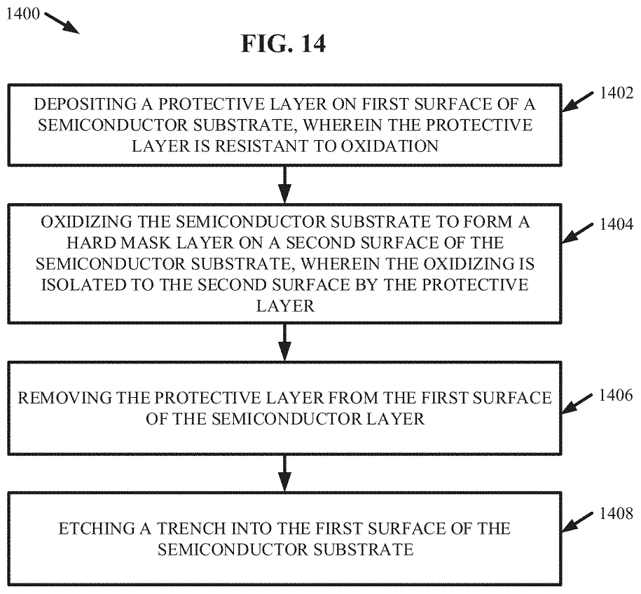

FIG. 14 illustrates a flow diagram of an example, non-limiting method 1400 that can facilitate replenishment of one or more hard mask layers 104 to facilitate one or more etching processes in accordance with one or more embodiments described herein. Repetitive description of like elements employed in other embodiments described herein is omitted for sake of brevity.

At 1402, the method 1400 can comprise depositing one or more protective layers 402 on a first surface (e.g., one or more surfaces that can define one or more trenches 202 extending into the semiconductor substrate 102) of a semiconductor substrate 102, wherein the one or more protective layers 402 can be resistant to oxidation. For example, the depositing at 1402 can be performed in accordance with the fourth stage of the replenishment process 100 described herein. For instance, the one or more protective layers 402 can be deposited such that the one or more protective layers 402 have a greater thickness in the one or more trenches 202 adjacent to the one or more columns 204 than on a top surface 106 of the semiconductor substrate 102, which can be located at the distal ends of the one or more columns 204. An example deposition method that can facilitate the varying thickness of the one or more protective layers 402 can be an ALD with post-dose treatment. Additionally, one of ordinary skill in the art will recognize that alternate deposition methods can also be employed to facilitate the depositing at 1206.

At 1404, the method 1400 can comprise oxidizing a semiconductor substrate 102 to form one or more hard mask layers 104 on a second surface (e.g., a top surface 106) of the semiconductor substrate 102. For example, the oxidizing at 1302 can be performed in accordance with the seventh stage of the replenishment process 100 described herein. For instance, the oxidizing at 1302 can be directed by the one or more protective layers 402 to selectively position the replenishment of the one or more hard mask layers 104 onto the second surface (e.g., the top surface 106) of the semiconductor substrate 102.

At 1406, the method 1400 can comprise removing the one or more protective layers 402 from the first surface of the semiconductor substrate 102 (e.g., from the one or more trenches 202). For example, removing the one or more protective layers 402 can be performed in accordance with the eighth stage of the replenishment process 100 described herein. For instance, the one or more protective layers 402 can be removed by one or more etching processes, which can include, but are not limited to: RIE, wet etching, dry etching, plasma etching, sputter etching, a combination thereof, and/or the like.

At 1408, the method 1400 can comprise etching one or more trenches 202 into the first surface of the semiconductor substrate 102. For example, the etching at 1408 can be performed in accordance with the ninth stage of the replenishment process 100 described herein. For instance, etching the one or more trenches 202 can comprise deepening one or more existing trenches 202 formed by one or more previous etching processes. Further, in one or more embodiments, the one or more previous etching processes could have diminished a thickness of the one or more hard mask layers 104, thereby necessitating the oxidizing at 1404 to replenish the thickness of the one or more hard mask layers 104 and facilitate the etching at 1408.

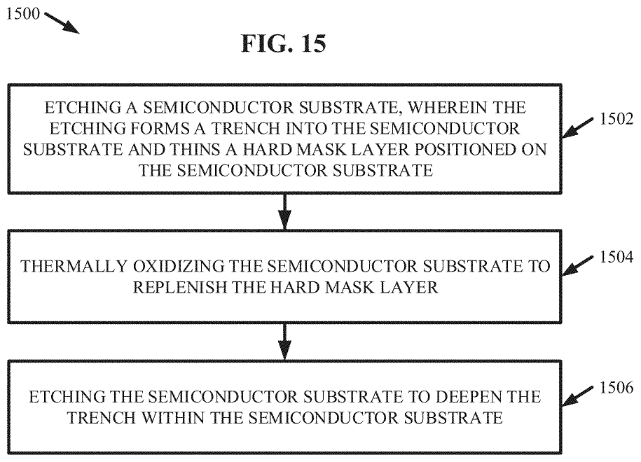

FIG. 15 illustrates a flow diagram of an example, non-limiting method 1500 that can facilitate replenishment of one or more hard mask layers 104 to facilitate one or more etching processes in accordance with one or more embodiments described herein. Repetitive description of like elements employed in other embodiments described herein is omitted for sake of brevity.

At 1502, the method 1500 can comprise etching a semiconductor substrate 102, wherein the etching can form one or more trenches 202 into the semiconductor substrate 102 and/or thin one or more hard mask layers 104 positioned on the semiconductor substrate 102. For example, the etching at 1502 can be performed in accordance with the second stage of the replenishment process 100 described herein. For instance, the depth of the one or more trenches 202 can depend on a thickness of the one or more hard mask layers 104. Example processes that can facilitate the etching at 1502 can include, but are not limited to: RIE, wet etching, dry etching, plasma etching, sputter etching, a combination thereof, and/or the like.

At 1504, the method 1500 can comprise thermally oxidizing the semiconductor substrate 102 to replenish the one or more hard mask layers 104. For example, thermal oxidation at 1504 can be performed in accordance with the third, fourth, fifth, sixth, and/or seventh stage of the replenishment process 100 described herein. For instance, oxidizing the semiconductor substrate 102 can form one or more hard mask layers 104 having a thickness large enough to facilitate one or more subsequent etching processes. For example, the replenishment of the one or more hard mask layers 104 facilitated by the oxidizing at 1504 can result in the hard mask layers 104 having a thickness greater than or equal to their original thickness prior to the etching at 1502.

At 1506, the method 1500 can comprise etching the semiconductor substrate 102 to deepen the one or more trenches 202 within the semiconductor substrate 102. For example, the etching at 1506 can be performed in accordance with the ninth stage of the replenishment process 100 described herein. For instance, the oxidizing at 1504 can render one or more hard mask layers 104 thick enough to facilitate the etching at 1506. The etching at 1506 can remove oxide material from the one or more hard mask layers 104 in addition to semiconductor material from the semiconductor substrate 102; thus, a previous thickness of the one or more hard mask layers 104 (e.g., a thickness resulting from the thinning caused by the etching at 1502) can be insufficient to facilitate the etching at 1506 while properly protecting one or more select portions of the semiconductor substrate 102 (e.g., the one or more columns 204 defined by the one or more trenches 202). By replenishing the one or more hard mask layers 104 via the thermal oxidation at 1504, the method 1500 can facilitate deep etches into the semiconductor substrate 102 while minimizing the necessary thickness of the one or more hard mask layers 104. Further, by minimizing the necessary thickness of the one or more hard mask layers 104, the method 1500 can reduce various aspect ratios of the semiconductor substrate 102 during a manufacturing processes; thereby enhancing structural stability of the semiconductor substrate 102.

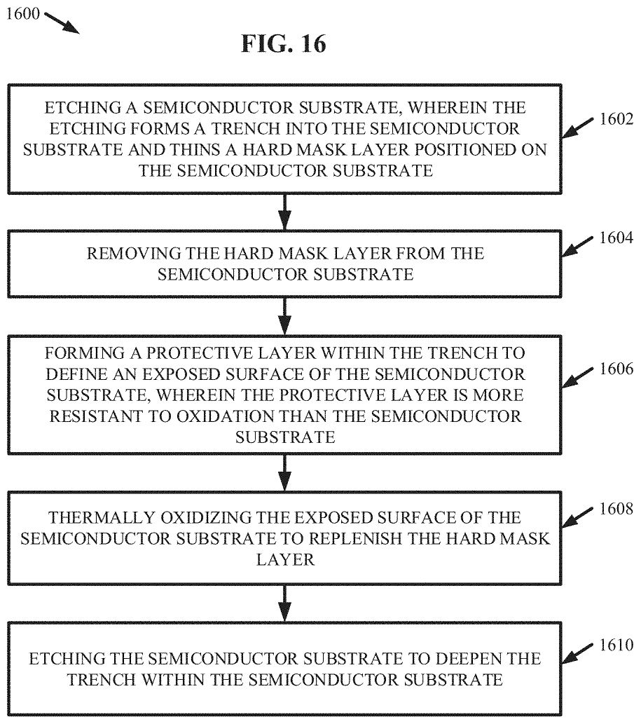

FIG. 16 illustrates a flow diagram of an example, non-limiting method 1600 that can facilitate replenishment of one or more hard mask layers 104 to facilitate one or more etching processes in accordance with one or more embodiments described herein. Repetitive description of like elements employed in other embodiments described herein is omitted for sake of brevity.

At 1602, the method 1600 can comprise etching a semiconductor substrate 102, wherein the etching can form one or more trenches 202 into the semiconductor substrate 102 and/or thin one or more hard mask layers 104 positioned on the semiconductor substrate 102. For example, the etching at 1602 can be performed in accordance with the second stage of the replenishment process 100 described herein. For instance, the depth of the one or more trenches 202 can depend on a thickness of the one or more hard mask layers 104. Example processes that can facilitate the etching at 1602 can include, but are not limited to: RIE, wet etching, dry etching, plasma etching, sputter etching, a combination thereof, and/or the like.

At 1604, the method 1600 can comprise removing the one or more hard mask layers 104 from the semiconductor substrate 102. For example, removing the one or more hard mask layers 104 at 1604 can be performed in accordance with the third stage of the replenishment process 100 described herein. For instance, the one or more hard mask layers 104 can be removed from a top surface 106 of the semiconductor substrate 102 through one or more etching processes, which can include, but are not limited to: RIE, wet etching, dry etching, plasma etching, sputter etching, a combination thereof, and/or the like.

At 1606, the method 1600 can comprise forming one or more protective layers 402 within the one or more trenches 202 to define one or more exposed surfaces (e.g., a top surface 106) of the semiconductor substrate 102, wherein the one or more protective layers 402 can be more resistant to oxidation than the semiconductor substrate 102. For example, forming the one or more protective layers 402 at 1606 can be performed in accordance with fourth and/or fifth stage of the replenishment process 100 described herein. For instance, forming the one or more protective layers 402 can comprise depositing the one or more protective layers 402 onto the semiconductor substrate 102 and removing select portions of the one or more deposited protective layers 402. The one or more select portions can be located on the top surface 106 of the semiconductor substrate 102 located at the distal ends of the one or more columns 204 defined by the one or more trenches 202. Thus, the one or more protective layers 402 can be formed in the one or more trenches 202 through deposition and/or removal, wherein the absence of one or more protective layers 402 at one or more positions on the semiconductor substrate 102 can define the one or more exposed surfaces.

At 1608, the method 1600 can comprise thermally oxidizing the one or more exposed surfaces of the semiconductor substrate 102 to replenish the one or more hard mask layers 104. For example, thermal oxidation at 1608 can be performed in accordance with the sixth, and/or seventh stage of the replenishment process 100 described herein. For instance, oxidizing the semiconductor substrate 102 can form one or more hard mask layers 104 having a thickness large enough to facilitate one or more subsequent etching processes. For example, the replenishment of the one or more hard mask layers 104 facilitated by the oxidizing at 1608 can result in the hard mask layers 104 having a thickness greater than or equal to their original thickness prior to the etching at 1602. Additionally, the thermal oxidation at 1608 can be directed by the one or more protective layers 402 deposited at 1606.

At 1610, the method 1600 can comprise etching the semiconductor substrate 102 to deepen the one or more trenches 202 within the semiconductor substrate 102. For example, the etching at 1610 can be performed in accordance with the eighth stage and/or ninth stage of the replenishment process 100 described herein. For instance, the oxidizing at 1608 can render one or more hard mask layers 104 thick enough to facilitate the etching at 1610. The etching at 1610 can remove oxide material from the one or more hard mask layers 104 in addition to semiconductor material from the semiconductor substrate 102; thus, a previous thickness of the one or more hard mask layers 104 (e.g., a thickness resulting from the thinning caused by the etching at 1502) can be insufficient to facilitate the etching at 1610 while properly protecting one or more select portions of the semiconductor substrate 102 (e.g., the one or more columns 204 defined by the one or more trenches 202). By replenishing the one or more hard mask layers 104 via the thermal oxidation at 1608, the method 1600 can facilitate deep etches into the semiconductor substrate 102 while minimizing the necessary thickness of the one or more hard mask layers 104. Further, by minimizing the necessary thickness of the one or more hard mask layers 104, the method 1600 can reduce various aspect ratios of the semiconductor substrate 102 during a manufacturing processes; thereby enhancing structural stability of the semiconductor substrate 102.

One of ordinary skill in the art will recognize that the various features of the replenishment process 100 and/or the methods (e.g., method 1100, method 1200, method 1300, method 1400, method 1500, and/or method 1600) described herein can be repeated one or more times to facilitate one or more manufacturing processes of semiconductor devices. For example, the various features and/or processes described herein can be repeated to facilitate multiple etching processes while utilizing thin masking layers to minimize aspect ratios during the manufacturing process.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

It is, of course, not possible to describe every conceivable combination of components, products and/or methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method, comprising:
replenishing an oxide layer onto a surface of a semiconductor substrate by thermally oxidizing the surface of the semiconductor substrate, wherein the oxide layer facilitates selective etching of the semiconductor substrate;
depositing a protective layer onto a fin structure of the semiconductor substrate, wherein the fin structure comprises a column of the semiconductor substrate extending from a base of the semiconductor substrate; and
etching away a portion of the protective layer from the column of the semiconductor substrate to expose the surface of the semiconductor substrate.

2. (canceled)

3. The method of claim 1, wherein the protective layer comprises silicon nitride.

4. (canceled)

5. The method of claim 1, further comprising:
etching the surface of the semiconductor substrate to shorten the column of the semiconductor substrate.

6. The method of claim 1, further comprising:
thermally oxidizing the surface to form the oxide layer, wherein formation of the oxide layer is directed along a length of the column of the semiconductor substrate by the protective layer.

7. The method of claim 6, further comprising:
removing the protective layer from the fin structure; and
etching into the base of the semiconductor substrate, wherein the oxide layer has greater resistance to the etching than the semiconductor substrate.

8. The method of claim 7, wherein the semiconductor substrate comprises silicon, and wherein the oxide layer comprises silicon dioxide.

9. A method, comprising:
oxidizing a semiconductor substrate to form a hard mask layer on a first surface of the semiconductor substrate;
depositing a protective layer onto a structure of the semiconductor substrate, wherein the structure comprises a column extending from a base of the semiconductor substrate; and
etching away a portion of the protective layer from the column of the semiconductor substrate to expose a second surface of the semiconductor substrate.

10. The method of claim 9, wherein the oxidizing comprises thermally oxidizing the semiconductor substrate, and wherein the hard mask layer comprises an oxide material.

11. The method of claim 10, wherein the semiconductor substrate comprises silicon, and wherein the oxide material is silicon dioxide.

12. The method of claim 10, wherein the hard mask layer is not positioned on the second surface of the semiconductor substrate.

13. The method of claim 10, wherein the first surface is located at a distal end of the column of semiconductor substrate, and wherein the second surface is located at the base of the semiconductor substrate.

14. The method of claim 13,
wherein the depositing comprises depositing the protective layer on the second surface of the semiconductor substrate such that the oxidizing is isolated to the first surface, and wherein the protective layer is resistant to oxidation.

15. The method of claim 14, wherein the protective layer comprises silicon nitride.

16. The method of claim 14, wherein the etching extends a length of the column of semiconductor substrate.

17. A method, comprising:
etching a semiconductor substrate, wherein the etching forms a trench into the semiconductor substrate and thins hard mask layers positioned on the semiconductor substrate, wherein the hard mask layers are positioned at distinct, disparate locations along a surface of the semiconductor substrate and a first hard mask layer is separate from a second hard mask layer prior to the etching, and wherein the trench is formed between the first hard mask layer and the second hard mask layer;
thermally oxidizing the semiconductor substrate to replenish the hard mask layers; and
etching the semiconductor substrate to deepen the trench within the semiconductor substrate.

18. The method of claim 17, further comprising:
removing the hard mask layers from the semiconductor substrate.

19. The method of claim 18, further comprising:
forming a protective layer within the trench to define an exposed surface of the semiconductor substrate that is subject to the thermally oxidizing, wherein the protective layer is more resistant to thermal oxidation than the semiconductor substrate.

20. The method of claim 19, wherein the semiconductor substrate comprises silicon, wherein the hard mask layers comprise silicon dioxide, and wherein the protective layer comprises silicon nitride.
